(19) United States
(12) Patent Application Publication
(10) Pub. No.: US 2026/0096230 A1
(43) Pub. Date: Apr. 2, 2026

(54) IMAGE SENSOR AND ELECTRONIC APPARATUS INCLUDING THE SAME

(71) Applicant: SAMSUNG ELECTRONICS CO., LTD., Suwon-si (KR)

(72) Inventors: Sookyoung ROH, Suwon-si (KR); Soongeun JANG, Suwon-si (KR); Seokho YUN, Suwon-si (KR)

(73) Assignee: SAMSUNG ELECTRONICS CO., LTD., Suwon-si (KR)

(21) Appl. No.: 19/345,893

(22) Filed: Sep. 30, 2025

(30) Foreign Application Priority Data
Oct. 2, 2024 (KR) 10-2024-0134215

(51) Int. Cl. H10F 39/00; G01J 3/02; G01J 3/28

(52) U.S. Cl. CPC H10F 39/8027; G01J 3/0208; G01J 3/2803; G01J 3/2823; H10F 39/8053; H10F 39/8063; G01J 2003/2826

(57) ABSTRACT

An image sensor and an electronic apparatus including the image sensor may be provided. The image sensor may include a sensor substrate including photodetection cells corresponding to unit pixels, a spacer layer on the sensor substrate, and a color separation lens array on the spacer layer and including nanostructures configured to split incident light according to wavelengths of the incident light within each of the unit pixels and collect the split incident light in corresponding pixels. Each of the unit pixels may include pixels, at least two pixels of each of the unit pixels may detect light of an identical wavelength, and a wavelength of light detected by the at least of one of the unit pixels may be different from a wavelength of light detected by the at least two pixels of another one of the unit pixels.

### CROSS-REFERENCE TO RELATED APPLICATION

This application is based on and claims priority under 35 U.S.C. § 119 to Korean Patent Application No. 10-2024-0134215, filed on Oct. 2, 2024, in the Korean Intellectual Property Office, the disclosure of which is incorporated by reference herein in its entirety.

### BACKGROUND

### 1. Field

The disclosure relates to an image sensor and an electronic apparatus including the image sensor, and more particularly, to a meta-pixel image sensor including a pixel array in which a pixel color combination and an arrangement of nanostructures vary in unit pixels, and an electronic apparatus including the image sensor.

### 2. Description of Related Art

The number of pixels in image sensors has steadily increased, which in turn necessitates pixel miniaturization. Ensuring sufficient light and noise reduction are critical issues for pixel miniaturization.

Image sensors typically use color filters to display images in various colors or to detect a color of incident light. However, color filters absorb all colors of light except a targeted color, leading to a decline in a light utilization efficiency. For example, red, green, blue (RGB) color filters transmit only ⅓ of incident light while absorbing the remaining ⅔, resulting in a light utilization efficiency of approximately 33%, which indicates significant light loss.

Recently, attempts have been made to improve a light utilization efficiency of image sensors by using color separation lens arrays. Color separation lens arrays may separate colors of incident light by utilizing diffraction or refraction characteristics of light that vary by wavelengths, and a directionality of each wavelength may be adjusted according to refractive indexes and shapes of the color separation lens arrays. In images sensors with a meta-pixel structure, color separation lens arrays may separate colors in unit pixels and deliver the colors to corresponding pixels.

### SUMMARY

Provided is a meta-pixel image sensor in which a pixel color combination and an arrangement of nanostructures vary in unit pixels.

According to an aspect of the disclosure, an electronic apparatus may be provided and include an image sensor in which a pixel color combination and an arrangement of nanostructures vary in unit pixels.

According to an aspect of the disclosure, an image sensor may include: a sensor substrate including a plurality of photodetection cells; a spacer layer on the sensor substrate; and a color separation lens array on the spacer layer and including a plurality of nanostructures, wherein the image sensor further including a plurality of unit pixels, each of the plurality of unit pixels including a plurality of pixels, wherein the plurality of pixels may be defined by respective ones of the plurality of photodetection cells, and by the plurality of nanostructures, wherein the plurality of nanostructures may be configured to split incident light according to wavelengths of the incident light within each of the plurality of unit pixels and collect the incident light, that is split, in corresponding ones of the plurality of pixels, wherein at least two pixels, from among the plurality of pixels, of each of the plurality of unit pixels may be configured to detect light of an identical wavelength, and wherein a wavelength of light detected by the at least two pixels of one of the plurality of unit pixels is different from a wavelength of light detected by the at least two pixels of another one of the plurality of unit pixels.

The plurality of unit pixels may include a first unit pixel and a second unit pixel, and the plurality of pixels of each of the first unit pixel and the second unit pixel may include a first pixel, a second pixel, and a third pixel, wherein the first pixel and the second pixel of the first unit pixel may be configured to detect light of a first wavelength, the third pixel of the first unit pixel may be configured to detect light of a wavelength different from the first wavelength, the first pixel and the second pixel of the second unit pixel may be configured to detect light of a second wavelength, the third pixel of the second unit pixel may be configured to detect light of a wavelength different from the second wavelength, and the second wavelength may be different from the first wavelength.

The plurality of unit pixels may include a first unit pixel, a second unit pixel, and a third unit pixel, and the plurality of pixels of each of the first unit pixel, the second unit pixel, and the third unit pixel may include a first pixel, a second pixel, and a third pixel, wherein the first pixel and the second pixel of the first unit pixel may be configured to detect light of a first wavelength, the third pixel of the first unit pixel may be configured to detect light of a wavelength different from the first wavelength, the first pixel and the second pixel of the second unit pixel may be configured to detect light of a second wavelength, the third pixel of the second unit pixel may be configured to detect light of a wavelength different from the second wavelength, the first pixel and the second pixel of the third unit pixel may be configured to detect light of a third wavelength, the third pixel of the third unit pixel may be configured to detect light of a wavelength different from the third wavelength, and the first wavelength, the second wavelength, and the third wavelength may be different from each other.

The plurality of unit pixels may define a plurality of unit patterns, wherein each of the plurality of unit patterns may include, from among the plurality of unit pixels, a first unit pixel, a second unit pixel, a third unit pixel, and a fourth unit pixel that may be arranged in a 2×2 array, wherein each of the first unit pixel, the second unit pixel, the third unit pixel, and the fourth unit pixel may include, from among the plurality of pixels, a first pixel, a second pixel, a third pixel, and a fourth pixel arranged in a 2×2 array, wherein the first pixel and the second pixel of the first unit pixel may be configured to detect light of a first wavelength, the third pixel of the first unit pixel may be configured to detect light of a second wavelength, and the fourth pixel of the first unit pixel may be configured to detect light of a third wavelength, wherein the first pixel and the second pixel of the second unit pixel may be configured to detect the light of the second wavelength, the third pixel of the second unit pixel may be configured to detect the light of the third wavelength, and the fourth pixel of the second unit pixel may be configured to detect the light of the first wavelength, wherein the first pixel and the second pixel of the third unit pixel may be configured to detect the light of the third wavelength, the third pixel of the third unit pixel may be configured to detect the light of the first wavelength, and the fourth pixel of the third unit pixel may be configured to detect the light of the second wavelength, and wherein the first pixel and the second pixel of the fourth unit pixel may be configured to detect the light of the first wavelength, the third pixel of the fourth unit pixel may be configured to detect the light of the second wavelength, the fourth pixel of the fourth unit pixel may be configured to detect the light of the third wavelength, and the first wavelength, the second wavelength, and the third wavelength may be different from each other.

A number of the plurality of unit pixels that include at least two pixels, from among the plurality of pixels, that may be configured detect light of a first wavelength may be equal to k, wherein a number of the plurality of unit pixels that include at least two pixels, from among the plurality of pixels, that may be configured detect light of a second wavelength may be equal to I, wherein a number of the plurality of unit pixels that include at least two pixels, from among the plurality of pixels, that may be configured detect light of a third wavelength among the plurality of unit pixels may be equal to m, and wherein at least two from k, l, and m may be different from each other.

The plurality of nanostructures may be symmetrical with respect a diagonal direction within each of the plurality of unit pixels.

The first pixel and the second pixel of each of the plurality of unit pixels may be arranged with respect to each other in a first diagonal direction, and the plurality of nanostructures defining each of the plurality of unit pixels may be symmetrical with respect to a second diagonal direction different from the first diagonal direction.

The image sensor may include a first corresponding region that may be defined by the first pixel, and a second corresponding region that may be defined by the second pixel, and wherein an arrangement of the plurality of nanostructures in the first corresponding region may be a rotation of an arrangement of the plurality of nanostructures in the second corresponding region.

The at least two pixels of each of the plurality of unit pixels, which may be configured to detect the light of the identical wavelength, may be further configured to perform an autofocus function.

The image sensor may further include a plurality of optical diffusers on the color separation lens array and respectively corresponding to the plurality of unit pixels.

According to an aspect of the disclosure, the image sensor may further include a color filter layer between the sensor substrate and the spacer layer, the color filter layer including a plurality of color filters, wherein each of the plurality of color filters may be on the at least two pixels of each of the plurality of unit pixels, which may be configured to detect the light of the identical wavelength.

According to an aspect of the disclosure, an electronic apparatus may include: a lens assembly including at least one lens and configured to form an optical image of an object; an image sensor configured to convert the optical image formed by the lens assembly into an electrical signal; and a processor configured to process a signal generated by the image sensor, wherein the image sensor may include: a sensor substrate including a plurality of photodetection cells; a spacer layer on the sensor substrate; and a color separation lens array on the spacer layer and including a plurality of nanostructures, wherein the image sensor further includes a plurality of unit pixels, each of the plurality of unit pixels including a plurality of pixels, wherein the plurality of pixels may be defined by respective ones of the plurality of photodetection cells, and by the plurality of nanostructures, wherein the plurality of nanostructures may be configured to split incident light according to wavelengths of the incident light within each of the plurality of unit pixels and collect the incident light, that may be split, in corresponding ones of the plurality of pixels, wherein at least two pixels, from among the plurality of pixels, of each of the plurality of unit pixels may be configured to detect light of an identical wavelength, and wherein a wavelength of light detected by the at least two pixels of one of the plurality of unit pixels may be different from a wavelength of light detected by the at least two pixels of an identical wavelength of another one of the plurality of unit pixels.

Additional aspects will be set forth in part in the description which follows and, in part, will be apparent from the description, or may be learned by practice of the presented embodiments of the disclosure.

### BRIEF DESCRIPTION OF DRAWINGS

The above and other aspects, features, and advantages of certain example embodiments of the disclosure will be more apparent from the following description taken in conjunction with the accompanying drawings, in which:

FIG. 1 is a block diagram schematically illustrating an overall configuration of an image sensor according to an embodiment;

FIG. 2 is a plan view schematically illustrating a pixel array of an image sensor according to an embodiment;

FIG. 3 is a cross-sectional view taken along a line I-I′ of FIG. 2;

FIG. 4 is a cross-sectional view taken along a line II-II′ of FIG. 2;

FIG. 5 is a perspective view schematically illustrating some components of the pixel array of the image sensor shown in FIG. 2, according to an embodiment;

FIG. 6A is a plan view schematically illustrating an overall configuration of a color separation lens array of an image sensor according to an embodiment;

FIG. 6B is an enlarged view schematically illustrating a region of the color separation lens array shown in FIG. 6B;

FIG. 7 is a plan view schematically illustrating a pixel array of an image sensor according to an embodiment;

FIG. 8 is a plan view schematically illustrating an overall configuration of a color separation lens array corresponding to the pixel array shown in FIG. 7;

FIG. 9 is a plan view schematically illustrating a pixel array of an image sensor according to an embodiment;

FIG. 10 is a plan view schematically illustrating an overall configuration of a lens array corresponding to the pixel array shown in FIG. 9.

FIG. 11 is a perspective view schematically illustrating some components of the pixel array of the image sensor shown in FIG. 2, according to an embodiment;

FIG. 12 is a block diagram schematically illustrating an electronic apparatus including an image sensor according to an embodiment;

FIG. 13 is a block diagram schematically illustrating a camera module shown in FIG. 12, according to an embodiment.

FIG. 14 is a block diagram illustrating an electronic apparatus including multiple camera modules, according to an embodiment.

FIG. 15 is a block diagram illustrating one of the multiple camera modules of the electronic apparatus shown in FIG. 14.

### DETAILED DESCRIPTION

Reference will now be made in detail to embodiments, examples of which are illustrated in the accompanying drawings, wherein like reference numerals refer to like elements throughout. In this regard, embodiments of the present disclosure may have different forms and should not be construed as being limited to the descriptions set forth herein. Accordingly, the example embodiments are merely described below, by referring to the figures, to explain example aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, image sensors including color separation lens arrays, and electronic apparatuses including the image sensors will be described with reference to the accompanying drawings. The example embodiments described herein are for illustrative purposes only, and various modifications may be made therein. In the drawings, like reference numerals refer to like elements, and the sizes of elements may be exaggerated for clarity of illustration.

In the following description, when an element is referred to as being “above” or “on” another element, it may be directly on an upper, lower, left, or right side of the other element while in contact with the other element or may be above an upper, lower, left, or right side of the other element without in contact with the other element.

Although the terms “first” and “second” are used to describe various elements, these terms are only used to distinguish one element from another element. These terms do not limit elements to having different materials or structures.

The terms of a singular form may include plural forms unless otherwise mentioned. It will be further understood that the terms “comprises” (or “includes”) and/or “comprising” (or “including”) used herein specify the presence of stated features or elements, but do not preclude the presence or addition of one or more other features or elements.

In the disclosure, terms such as “unit” or “module” may be used to denote a unit that has at least one function or operation and is implemented with hardware, software, or a combination of hardware and software.

An element referred to with the definite article or a demonstrative determiner may be construed as the element or the elements even though it has a singular form. In addition, examples or exemplary terms (e.g., “such as” and “etc.”) are used for the purpose of description and are not intended to limit the scope of the disclosure.

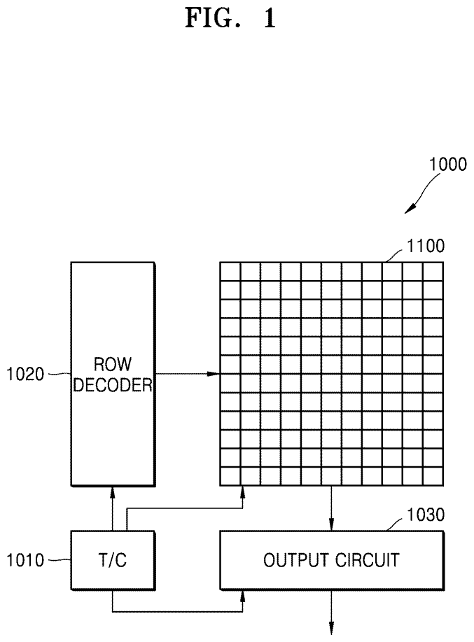

FIG. 1 is a schematic block diagram illustrating an image sensor 1000.

Referring to FIG. 1, the image sensor 1000 may include a pixel array 1100, a timing controller 1010, a row decoder 1020, and an output circuit 1030. The image sensor 1000 may be a charge-coupled device (CCD) image sensor or a complementary metal-oxide-semiconductor (CMOS) image sensor.

The pixel array 1100 may include pixels arranged two-dimensionally in a plurality of rows and a plurality of columns. The row decoder 1020 may select one of rows of the pixel array 1100 in response to a row address signal output from the timing controller 1010. The output circuit 1030 may output a photodetection signal in units of columns from a plurality of pixels arranged in the selected row. To this end, the output circuit 1030 may include a column decoder and an analog-to-digital converter (ADC). For example, the output circuit 1030 may include a plurality of ADCs provided respectively for the columns between the column decoder and the pixel array 1100, or may include a single ADC provided at an output terminal of the column decoder. The timing controller 1010, the row decoder 1020, and the output circuit 1030 may be implemented on a single chip or separate chips. A processor for processing image signals output through the output circuit 1030 may also be implemented on the same chip together with the timing controller 1010, the row decoder 1020, and the output circuit 1030.

The pixel array 1100 may include a plurality of pixels configured to detect light of different wavelengths. The pixel arrangement of the pixel array 1100 may be implemented in various manners. For example, the pixel array 1100 may have a pixel arrangement described below.

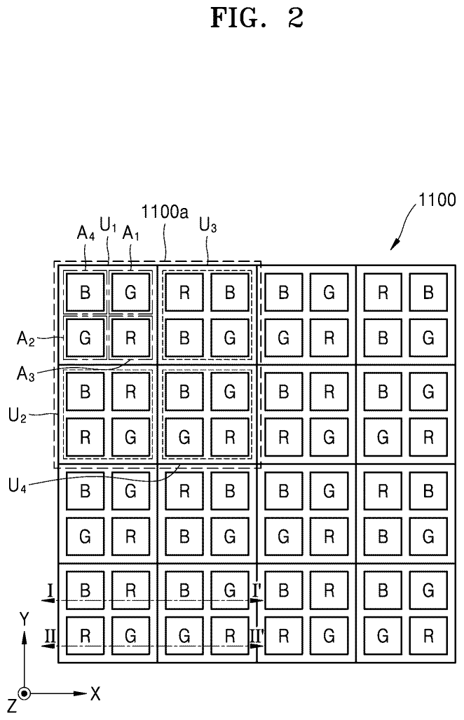

FIG. 2 is a schematic plan view illustrating the pixel array 1100 of the image sensor 1000 according to an embodiment.

Referring to FIG. 2, unit patterns 1100a may each include a plurality of unit pixels. For example, each of the unit patterns 1100a may include an N×N array of unit pixels, where N may be 2 or greater. For example, as illustrated in FIG. 2, each of the unit patterns 1100a may include a 2×2 array of first to fourth unit pixels U₁, U₂, U₃, and U₄. For example, the first unit pixel U₁ may be located in a first row and a first column of the unit pattern 1100a, the second unit pixel U₂ may be located in a second row and the first column of the unit pattern 1100a, the third unit pixel U₃ may be located in the first row and a second column of the unit pattern 1100a, and the fourth unit pixel U₄ may be located in the second row and second column of the unit pattern 1100a.

Each of the first to fourth unit pixels U₁, U₂, U₃, and U₄ may include a plurality of pixels. For example, each of the first to fourth unit pixels U₁, U₂, U₃, and U₄ may include an M×M array of pixels, where M may be 2 or greater. For example, as illustrated in FIG. 2, each of the first to fourth unit pixels U₁, U₂, U₃, and U₄ may include a 2×2 array of first to fourth pixels A₁, A₂, A₃, and A₄. For example, the first pixel A₁ may be located in a first row and a second column of each of the first to fourth unit pixels U U₂, U₃, and U₄, the second pixel A₂ may be located in a second row and a first column of each of the first to fourth unit pixels U₁, U₂, U₃, and U₄, the third pixel A₃ may be located in the second row and the second column of each of the first to fourth unit pixels U₁, U₂, U₃, and U₄, and the fourth pixel A₄ may be located in the first row and the first column of each of the first to fourth unit pixels U₁, U₂, U₃, and U₄.

Pixels configured to detect light of the same wavelength may be provided in each of the first to fourth unit pixels U₁, U₂, U₃, and U₄. For example, in each of the first to fourth unit pixels U₁, U₂, U₃, and U₄, the first pixel A₁ and the second pixel A₂ may be configured to detect light of the same wavelength, and the third pixel A₃ and the fourth pixel A₄ may be configured to detect light of wavelengths different from the wavelength detectable by the first pixel A₁ and the second pixel A₂. For example, as illustrated in FIG. 2, in the first unit pixel U₁, the first pixel A₁ and the second pixel A₂ may be green pixels G, the third pixel A₃ may be a red pixel R, and the fourth pixel A₄ may be a blue pixel B.

The colors of pixels that detect light of the same wavelength within each of the first to fourth unit pixels U₁, U₂, U₃, and U₄ may be different across at least two of the first to fourth unit pixels U₁, U₂, U₃, and U₄. For example, the first pixel A₁ and the second pixel A₂ of the first unit pixel U₁ may be configured to detect light of a first wavelength, the first pixel A₁ and the second pixel A₂ of the second unit pixel U₂ may be configured to detect light of a second wavelength, and the second wavelength may be different from the first wavelength. In this manner, the colors of pixels configured to detect light of the same wavelength within each of the first to fourth unit pixels U₁, U₂, U₃, and U₄ may vary across the first to fourth unit pixels U₁, U₂, U₃, and U₄.

For example, as illustrated in FIG. 2, the first pixel A₁ and the second pixel A₂ of the first unit pixel U₁ may be green pixels G, the first pixel A₁ and the second pixel A₂ of the second unit pixel U₂ may be red pixels R, the first pixel A₁ and the second pixel A₂ of the third unit pixel U₃ may be blue pixels B, and the first pixel A₁ and the second pixel A₂ of the fourth unit pixel U₄ may be green pixels G.

Although FIG. 2 illustrates an example in which the first pixel A₁ and the second pixel A₂ that are diagonally arranged in each of the first to fourth unit pixels U₁, U₂, U₃, and U₄ are configured to detect light of the same wavelength, embodiments are not limited thereto. For example, at least any two of the pixels provided in each of the first to fourth unit pixels U₁, U₂, U₃, and U₄ may detect light of the same wavelength.

In terms of the overall pixel arrangement, each of the unit patterns 1100a may include an (N×M)×(N×M) array of pixels. For example, as shown in FIG. 2, each of the unit patterns 1100a may include a 4×4 array of pixels. The unit patterns 1100a may be repeatedly arranged two-dimensionally in a first direction (X-direction) and a second direction (Y-direction).

Although FIG. 2 illustrates that the unit patterns 1100a are repeatedly arranged two-dimensionally, the pixel array 1100 illustrated in FIG. 2 is only an example. The pixel array 1100 may have variously arranged patterns. For example, the colors of pixels that detect light of the same wavelength within each of the first to fourth unit pixels U₁, U₂, U₃, and U₄ may be randomly distributed across the pixel array 1100. Even in this case, the colors of pixels detecting light of the same wavelength within each of the first to fourth unit pixels U₁, U₂, U₃, and U₄ of the pixel array 1100 may be at least two.

Hereinafter, the case in which the pixel array 1100 has a pattern structure like that shown in FIG. 2 is described. However, the following description is not limited to pattern structures similar to that shown in FIG. 2 but may be applied to pixel arrays having other pattern structures.

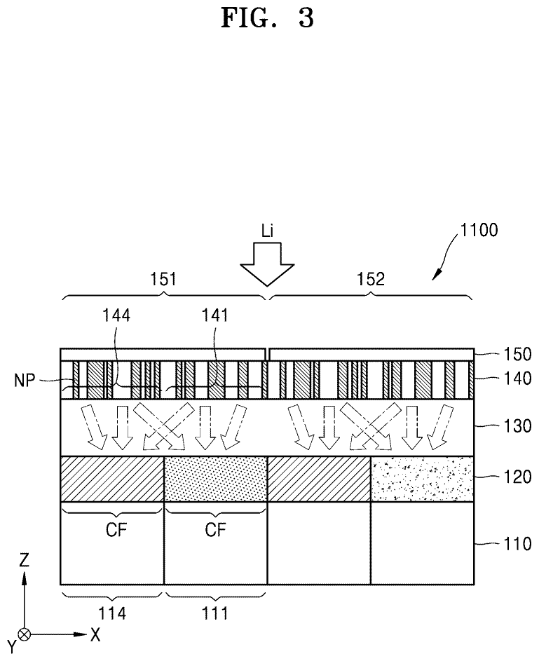

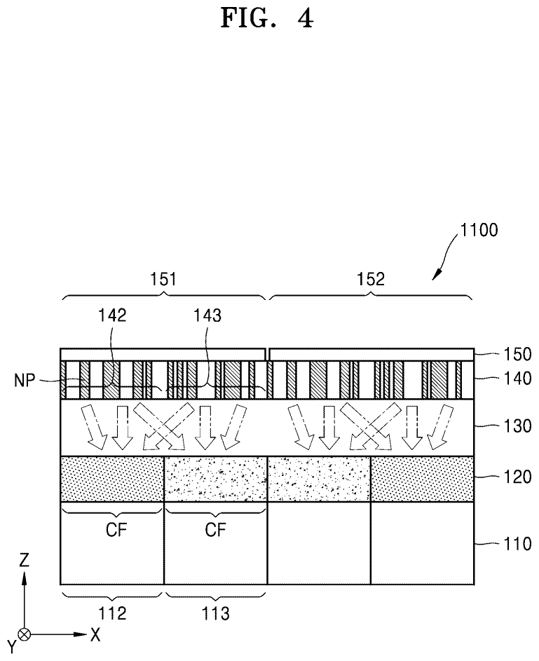

FIGS. 3 and 4 are schematic cross-sectional views illustrating a configuration of the pixel array 1100 of the image sensor 1000 according to an embodiment. FIG. 3 is a cross-sectional view taken along a line I-I of FIG. 2, and FIG. 4 is a cross-sectional view taken along a line II-II of FIG. 2.

Referring to FIGS. 3 and 4, the pixel array 1100 may include a sensor substrate 110, a color filter layer 120 provided on the sensor substrate 110, a spacer layer 130 provided on the color filter layer 120, a color separation lens array 140 provided on the spacer layer 130, and an optical diffuser 150 provided on the color separation lens array 140.

The sensor substrate 110 may include a plurality of first to fourth photodetection cells 111, 112, 113, and 114 configured to convert light into electrical signals. The first to fourth photodetection cells 111, 112, 113, and 114 may be provided in pixels, respectively. This segmentation of the sensor substrate 110 may be for detecting incident light by dividing the incident light into unit patterns. For example, the first photodetection cell 111 and the second photodetection cell 112 may detect light of a first wavelength, the third photodetection cell 113 may detect light of a second wavelength, and the fourth photodetection cell 114 may detect light of a third wavelength. The first to fourth photodetection cells 111, 112, 113, and 114 may be arranged in a 2×2 array. For example, the first photodetection cell 111 and the fourth photodetection cell 114 may be arranged in the first direction (X-direction) with respect to each other, and the first photodetection cell 111 and the third photodetection cell 113 may be arranged in the second direction (Y-direction) with respect to each other. The first photodetection cell 111 and the second photodetection cell 112 may be diagonally arranged with respect to each other, and the third photodetection cell 113 and the fourth photodetection cell 114 may be diagonally arranged with respect to each other. For example, the first photodetection cell 111 and the second photodetection cell 112 may be arranged in a first diagonal direction with respect to each other, and the third photodetection cell 113 and the fourth photodetection cell 114 may be arranged in a second diagonal direction perpendicular to the first diagonal direction with respect to each other. Color filters CF may be provided respectively on the first to fourth photodetection cells 111, 112, 113, and 114.

The spacer layer 130 may be provided between the sensor substrate 110 and the color separation lens array 140 to maintain a constant gap and ensure the focal length of the color separation lens array 140. The spacer layer 130 may include a material that is transparent to visible light. For example, the spacer layer 130 may include a dielectric material such as SiO₂ or siloxane-based spin-on glass (SOG) that has a lower refractive index than a refractive index of nanostructures NP of the color separation lens array 140 and a low absorption rate in a visible light band.

The color separation lens array 140 may be divided in various manners. For example, the color separation lens array 140 may be divided into a first corresponding region 141 that corresponds to (e.g., defined by) the first photodetection cell 111 (or the first pixel A₁), a second corresponding region 142 that corresponds to (e.g., defined by) the second photodetection cell 112 (or the second pixel A₂), a third corresponding region 143 that corresponds to (e.g., defined by) the third photodetection cell 113 or (the third pixel A₃), and a fourth corresponding region 144 that corresponds to (e.g., defined by) the fourth photodetection cell 114 (or the fourth pixel A₄). For example, the first corresponding region 141 may correspond to the first photodetection cell 111 and be positioned above the first photodetection cell 111, and the second corresponding region 142 may correspond to the second photodetection cell 112 and be positioned above the second photodetection cell 112 For example, referring to FIGS. 3 and 4, the first to fourth corresponding regions 141, 142, 143, and 144 of the color separation lens array 140 may respectively face the first to fourth photodetection cells 111, 112, 113, and 114. The first to fourth corresponding regions 141, 142, 143, and 144 may be diagonally arranged in a 2×2 array in the first direction (X-direction) and the second direction (Y-direction). The color separation lens array 140 may include a plurality of nanostructures NP in each of the first to fourth corresponding regions 141, 142, 143, and 144. The nanostructures NP of the color separation lens array 140 may be configured to perform color separation only between adjacent pixels by splitting incident light based on the wavelength of the incident light. The nanostructures NP of the color separation lens array 140 may be configured to enable color separation within a unit pixel array (e.g., a 2×2 array). For example, the color separation lens array 140 may be configured such that when light Li is incident on the first to fourth corresponding regions 141, 142, 143, and 144, a first wavelength of the incident light Li may be collected in the first photodetection cell 111 and the second photodetection cell 112, a second wavelength of the incident light Li may be collected in the third photodetection cell 113, and a third wavelength of the incident light Li may be collected in the fourth photodetection cell 114.

The nanostructures NP of the color separation lens array 140 may create different phase profiles for the first and second wavelengths of the incident light Li to implement color separation only in a unit pixel array. The refractive index of a material varies with the wavelength of light that the material interacts with, and thus, the color separation lens array 140 may provide different phase profiles for first and second wavelengths of light. In other words, even for the same material, the refractive index differs depending on the wavelength of light interacting with the material, and the phase delay experienced by the light as the light passes through the material also varies with the wavelength of the light. This leads to the formation of different phase distributions for different wavelengths. For example, the first corresponding region 141 may have different refractive indexes for first and second wavelengths of light such that a phase delay of the first wavelength passing through the first corresponding region 141 may differ from a phase delay of the second wavelength passing through the first corresponding region 141. Thus, the color separation lens array 140 may be designed by considering these properties of light to provide different phase profiles for the first and second wavelengths. To this end, each of the first to fourth corresponding regions 141, 142, 143 and 144 of the color separation lens array 140 may include a plurality of cylindrical nanostructures NP.

Each of the first to fourth corresponding regions 141, 142, 143 and 144 of the color separation lens array 140 may include one or more nanostructures NP of which the shape, size, spacing, and/or arrangement varies by region. For example, each of the first to fourth corresponding regions 141, 142, 143 and 144 may include one or more nanostructures NP. The size, shape, spacing, and/or arrangement of the nanostructures NP may be determined such that a first wavelength of incident light of may be collected in the first photodetection cell 111 and the second photodetection cell 112, a second wavelength of the incident light may be collected in the third photodetection cell 113, and a third wavelength of the incident light may be collected in the fourth photodetection cell 114.

The cross-sectional diameter of the nanostructures NP may be a subwavelength dimension. Here, the term “subwavelength” refers to a wavelength less than the wavelength band of light to be split. For example, the nanostructures NP may have dimensions less than a first wavelength, a second wavelength, or a third wavelength, depending on the first to fourth corresponding regions 141, 142, 143, and 144. For example, for the case in which incident light Li is visible light, the nanostructures NP may have a cross-sectional diameter less than 400 nm, 300 nm, or 200 nm. According to some embodiments, the nanostructures NP may each be formed by stacking two or more posts in a height direction (Z-direction). In addition, although the color separation lens array 140 is illustrated as having a single-layer structure, the color separation lens array 140 may have a plurality of stacked layers.

The nanostructures NP may include a material with a higher refractive index than refractive indexes of surrounding materials and a relatively low absorption rate in a visible light band. For example, the nanostructures NP may include c-Si, p-Si, a-Si, a Group III-V compound semiconductor (e.g., GaP, GaN, or GaAs), SiC, TiO₂, SiN₃, ZnS, ZnSe, Si₃N₄, and/or a combination thereof. A region around the nanostructures NP may be filled with a material having a lower refractive index than a refractive index of the material of the nanostructures NP and a relatively low absorption rate in the visible light band. For example, the region around the nanostructures NP may be filled with SiO₂, siloxane-based SOG, or air. The nanostructures NP having a refractive index different from the refractive index of a material filled around the nanostructures NP may vary the phase of light passing through the nanostructures NP. The extent of phase delay induced by the color separation lens array 140 may be determined by, for example, the shapes, dimensions, and arrangement of the nanostructures NP.

The optical diffuser 150 may be provided on the color separation lens array 140. The optical diffuser 150 may include a plurality of optical diffusers (e.g., a first optical diffuser 151 and a second optical diffuser 152) corresponding to a unit pixel array. For example, when unit pixels are arranged in 2×2 arrays as shown in FIG. 2, the optical diffuser 150 may be divided so as to correspond to each of the 2×2 unit pixel arrays. The optical diffuser 150 may scatter incident light Li entering a unit pixel array (e.g., a 2×2 array) and distribute the incident light Li evenly across all the first to fourth corresponding regions 141, 142, 143, and 144. Light passing through the optical diffuser 150 and entering the color separation lens array 140 may undergo wavelength-based color separation in a unit pixel array due to the color separation lens array 140, and may then be collected in the first to fourth photodetection cells 111, 112, 113, and 114 according to the wavelengths of the light. This structure, in which incident light is split by color and collected in pixels having corresponding colors within a unit pixel array, may be referred to as a meta-pixel structure.

Although FIG. 4 illustrates that the optical diffuser 150 has a thin film structure, the structure of the optical diffuser 150 is not limited thereto. For example, the optical diffuser 150 may have a structure with one or more posts like the color separation lens array 140, or may have a structure with one or more holes. In addition, the optical diffuser 150 may have a curved shape. Alternatively, a microlens may be provided on the color separation lens array 140.

In addition, some of incident light Li may enter the color separation lens array 140 through the optical diffuser 150 without losing directionality, and in this case, the color separation lens array 140 may split colors of the light based on the wavelength of the light within a unit pixel array. Light having undergone wavelength-based color separation may exhibit a directional bias from the center of a unit pixel and may be collected in the first to fourth photodetection cells 111, 112, 113, and 114 corresponding thereto. Thus, images with parallax between color pixels may be captured, and a phase difference signal may be obtained from the images.

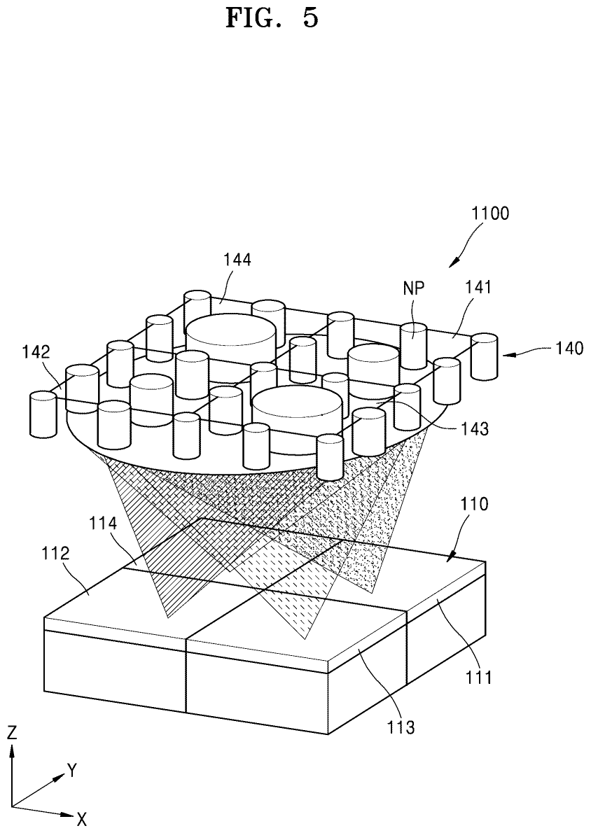

FIG. 5 is a schematic perspective view illustrating some components of the pixel array 1100 of the image sensor 1000 shown in FIG. 2, according to an embodiment. In FIG. 5, only some components are schematically depicted to clearly illustrate how the color separation lens array 140 splits and collects incident light according to the wavelength of the incident light.

Referring to FIG. 5, the pixel array 1100 of the image sensor 1000 may include the sensor substrate 110 and the color separation lens array 140, wherein the sensor substrate 110 may include an array of a plurality of photodetection cells configured to sense light, and the color separation lens array 140 may be disposed above the sensor substrate 110 to split and collect the light according to the colors of the light and direct the light onto the photodetection cells.

The color separation lens array 140 may include fine structures in the first to fourth corresponding regions 141, 142, 143, and 144 that respectively face the first to fourth photodetection cells 111, 112, 113, and 114. The fine structures may be configured to split and collect incident light according to the wavelength of the incident light by forming a phase distribution for collecting different wavelengths of light in adjacent pixels within a unit pixel array. As illustrated by example in FIGS. 3 and 4, the fine structures of the color separation lens array 140 may include a plurality of nanostructures NP to form a phase distribution for collecting different wavelengths of light in adjacent photodetection cells within a unit pixel array.

The color separation lens array 140 may include a plurality of regions such as the first to fourth corresponding regions 141, 142, 143, and 144 that respectively correspond to and face a plurality of photodetection cells of the sensor substrate 110 such as the first to fourth photodetection cells 111, 112, 113, and 114. For example, the color separation lens array 140 may include the first to fourth corresponding regions 141, 142, 143 and 144 that correspond to and face the first to fourth photodetection cells 111, 112, 113, and 114 of the sensor substrate 110 in a one-to-one manner. The first to fourth corresponding regions 141, 142, 143, and 144 may each include nanostructures NP to form a phase distribution for collecting different wavelengths of light in adjacent photodetection cells. For example, as illustrated in FIG. 5, the nanostructures NP may be arranged in the first to fourth corresponding regions 141, 142, 143, and 144 and may collect light only in the first to fourth corresponding regions 141, 142, 143, and 144.

The shapes, sizes, and arrangement of the nanostructures NP of the first to fourth corresponding regions 141, 142, 143, and 144 may be determined to form a phase for collecting a certain wavelength of light passing through the color separation lens array 140 in a corresponding one of the first to fourth photodetection cells 111, 112, 113, and 114 while preventing the certain wavelength from entering the other photodetection cells. The shapes, sizes, and arrangements of the nanostructures NP of the color separation lens array 140 are described below.

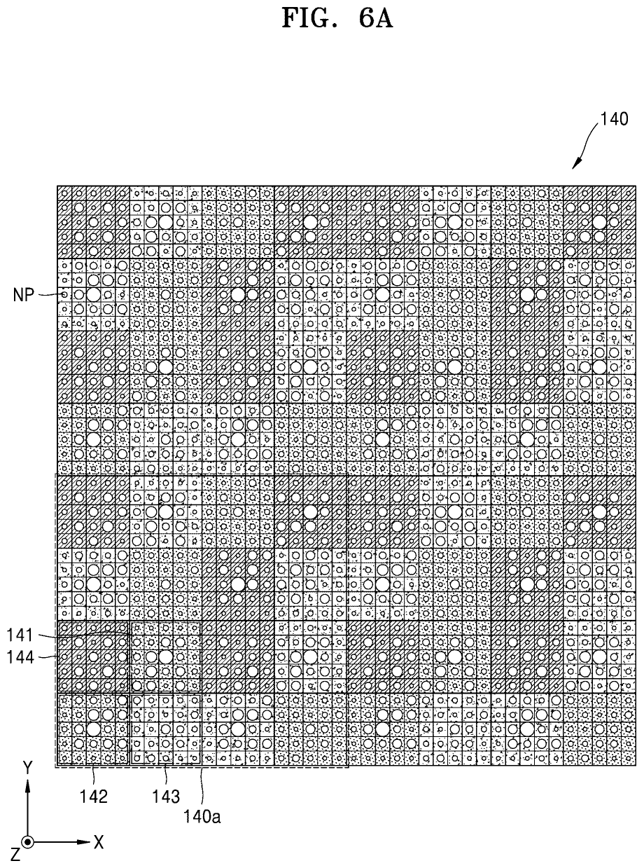

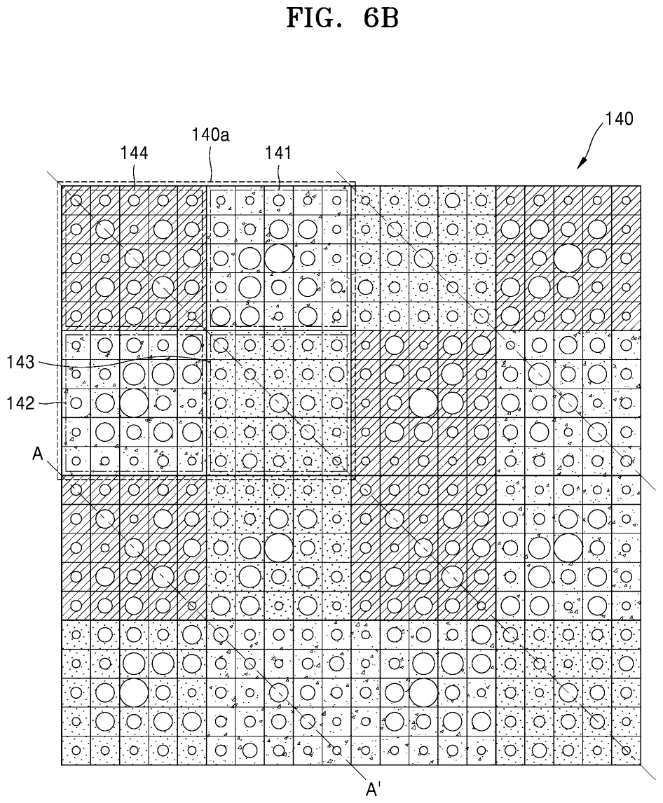

FIG. 6A is a schematic plan view illustrating an overall configuration of the color separation lens array 140 of the image sensor 1000 according to an embodiment, and FIG. 6B is an enlarged schematic view illustrating a color separation lens array region 140a shown in FIG. 6A.

Referring to FIGS. 6A and 6B, according to an embodiment, nanostructures NP provided in the color separation lens array region 140a corresponding to each of the unit pixels of the image sensor 1000 may vary depending on a color combination of the unit pixel and may be symmetrically arranged in a diagonal direction.

For example, as shown in FIG. 6B, the nanostructures NP provided in the color separation lens array region 140a corresponding to the unit pixel may be symmetrical with respect to a diagonal line A-A′ extending from a top-left end to a bottom-right end of the color separation lens array region 140a. The diagonal line A-A′ may be in a diagonal direction different from a diagonal direction in which first and second pixels are arranged. A plurality of nanostructures NP provided in a third corresponding region 143 and a fourth corresponding region 144 of the color separation lens array region 140a corresponding to the unit pixel may be symmetrical with respect to the diagonal line A-A′. However, a plurality of nanostructures NP provided in a first corresponding region 141 and a second corresponding region 142 of the color separation lens array region 140a corresponding to the unit pixel may not be symmetrical with respect to the diagonal line A-A′. The arrangement of the nanostructures NP provided in the first corresponding region 141 may be a rotated version of the arrangement of the nanostructures NP provided in the second corresponding region 142.

As described above, the nanostructures NP provided in the color separation lens array region 140a corresponding to each of the unit pixels may be symmetrical with respect to a diagonal direction. Thus, for the same wavelength of incident light, the image sensor 1000 may obtain, from the first photodetection cell 111 and the second photodetection cell 112, a signal indicating a phase difference (L/R contrast) between a lower-left region and an upper-right region based on the diagonal direction.

In addition, referring to FIGS. 2 and 6A, the colors of pixels configured to detect light of the same wavelength in each of the unit pixels of the pixel array 1100 are different across the unit pixels, and the nanostructures NP of the color separation lens array 140 are provided corresponding thereto. As a result, the image sensor 1000 may obtain phase difference signals for all colors (red, green, and blue) of light and may perform autofocusing using the phase difference signals. For example, referring to FIG. 2, a phase difference signal for green light may be obtained in the first unit pixel U₁ and the fourth unit pixel U₄, a phase difference signal for red light may be obtained in the second unit pixel U₂, and a phase difference signal for blue light may be obtained in the third unit pixel U₃.

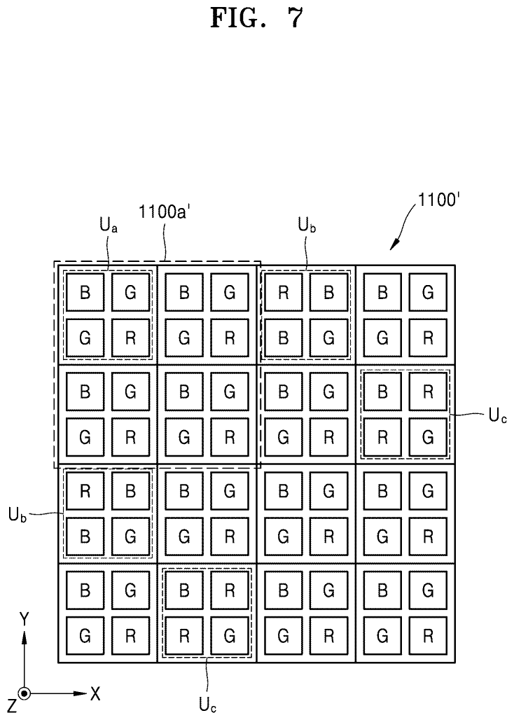

FIG. 7 is a schematic plan view illustrating a pixel array 1100′ of an image sensor according to an embodiment. FIG. 7 will now be described, focusing on the difference from FIG. 2.

Referring to FIG. 7, in the pixel array 1100′ of the image sensor of the embodiment, a plurality of pixels that detect light of the same wavelength in a plurality of reference unit pixels Uₐ (e.g., unit pixels used as references) have the same color, but a plurality of pixels that detect light of the same wavelength in some modified unit pixels U_{b} and U_{c} (e.g., unit pixels) have different colors across the modified unit pixels U_{b} and U_{c}.

For example, as illustrated in FIG. 7, first to fourth pixels of each of the reference unit pixels Uₐ may be a green pixel G, a green pixel G, a red pixel R, and a blue pixel B, respectively. First to fourth pixels of each of first modified unit pixels U_{b} may be a blue pixel B, a blue pixel B, a green pixel G, and a red pixel R, respectively, and first to fourth pixels of each of second modified unit pixels U_{c} may be a red pixel R, a red pixel R, a green pixel G, and a blue pixel B, respectively.

A 2×2 array of reference unit pixels Uₐ may be repeated to form a unit pattern 1100a′. Such unit patterns 1100a′ may be repeated in a two-dimensional configuration to form the pixel array 1100′. In the pixel array 1100′, some reference unit pixels Uₐ may be replaced with modified unit pixels (e.g., the first modified unit pixel U_{b} and the second modified unit pixel U_{c}). For example, in the pixel array 1100′, a certain unit pattern 1100a′ may include only reference unit pixels Uₐ without first modified unit pixel U_{b} and the second modified unit pixel U_{c}, while another unit pattern 1100a′ may include a first modified unit pixel U_{b}, a second modified unit pixel U_{c}, and reference unit pixels Uₐ as the other unit pixels.

Apart from the color combination described above, modified unit pixels (e.g., the first modified unit pixel U₃ and the second modified unit pixel U_{c}) may be variously arranged in the pixel array 1100′. For example, modified unit pixels (e.g., the first modified unit pixel U₃ and the second modified unit pixel U_{c}) may be randomly distributed throughout the pixel array 1100′. Alternatively, in the pixel array 1100′, reference unit pixels Uₐ and modified unit pixels (e.g., the first modified unit pixel U_{b} and the second modified unit pixel U_{c}) may be provided in different periodic arrangements according to the colors of pixels that detect light of the same wavelength in the modified unit pixels (e.g., the first modified unit pixel U_{b} and the second modified unit pixel U_{c}). That is, when the number of unit pixels each including a plurality of green pixels is k in a specific region of the pixel array 1100′, the number of unit pixels each including a plurality of blue pixels is l in the specific region of the pixel array 1100′, and the number of unit pixels each including a plurality of red pixels is m in the specific region of the pixel array 1100′, at least two of k, l, and m may be different from each other.

A plurality of pixels that detect light of the same wavelength in each of the reference unit pixels Uₐ may be provided to detect a certain color of light to improve autofocus performance for the specific color. For example, as illustrated in FIG. 7, when a plurality of pixels that detect light of the same wavelength in the reference unit pixels Uₐ are green pixels, a plurality of pixels that detect light of the same wavelength in the first modified unit pixels U_{b} are blue pixels, and a plurality of pixels that detect light of the same wavelength in the second modified unit pixels U_{c} are red pixels, autofocus performance may be higher for green light than for the other colors of light.

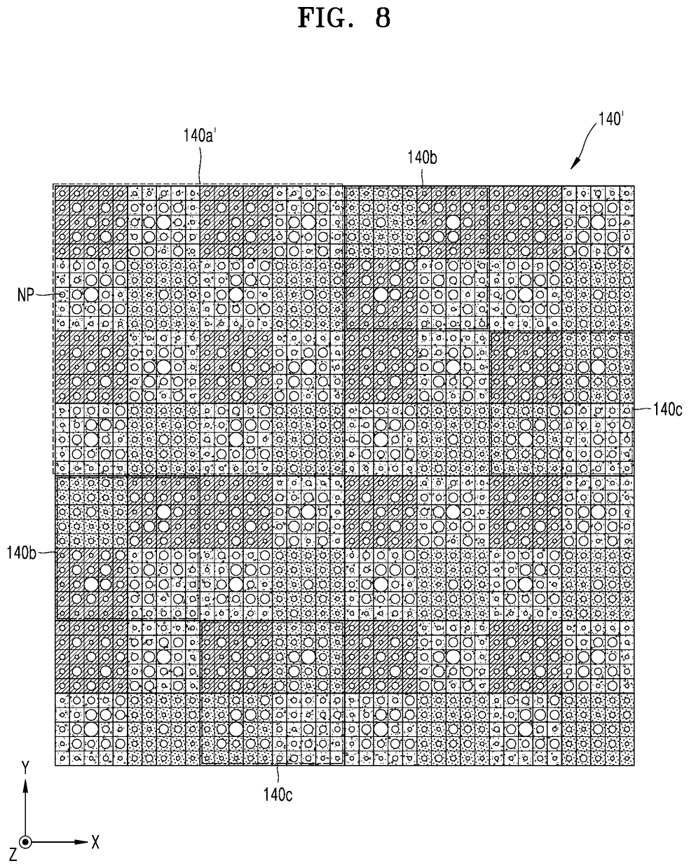

FIG. 8 is a schematic plan view illustrating an overall configuration of a color separation lens array 140′ corresponding to the pixel array 1100′ shown in FIG. 7.

Referring to FIG. 8, the color separation lens array 140′ may be provided on and correspond to the pixel array 1100′ shown in FIG. 7. The color separation lens array 140′ may include a plurality of reference color separation lens array regions 140a′ corresponding to the reference unit pixels Uₐ. Some of the reference color separation lens array regions 140′ may be changed to modified color separation lens array regions 140b and 140c corresponding to the modified unit pixels U_{b} and U_{c}. The modified color separation lens array regions 140b and 140c may include a plurality of nanostructures NP corresponding to the modified unit pixels U_{b} and U_{c}.

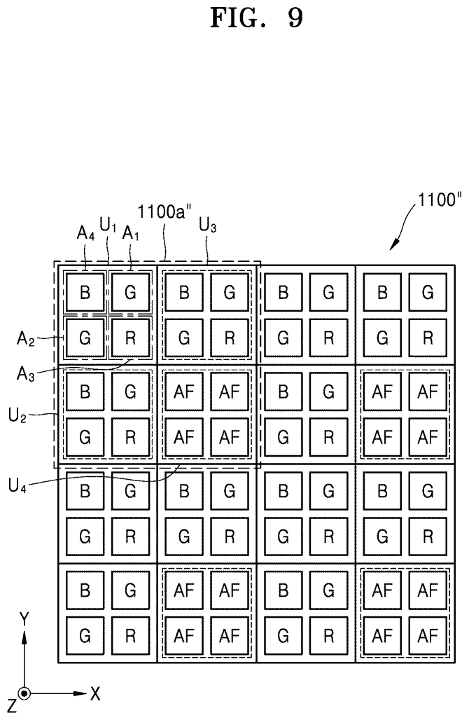

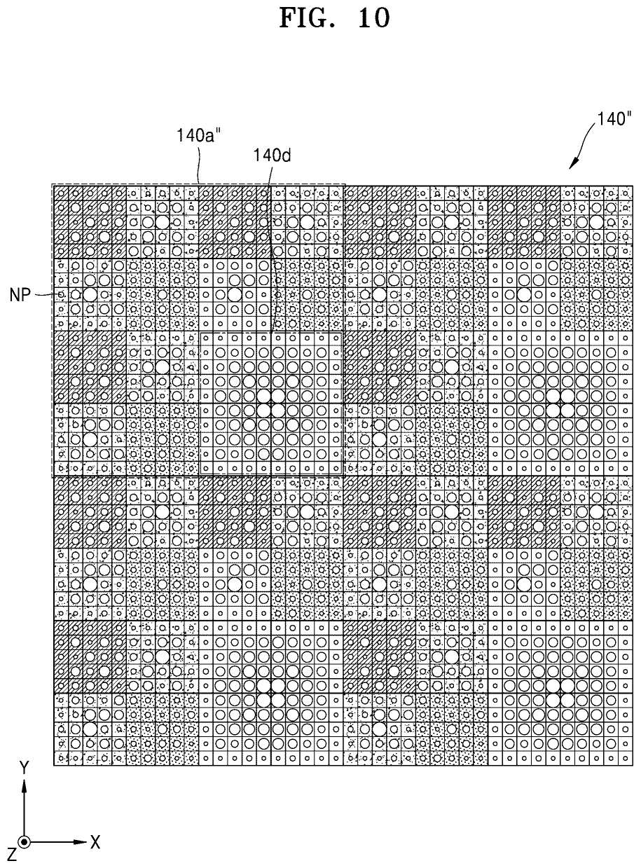

FIG. 9 is a schematic plan view illustrating a pixel array 1100″ of an image sensor according to an embodiment, and FIG. 10 is a schematic plan view illustrating an overall configuration of a lens array 140″ corresponding to the pixel array 1100″ shown in FIG. 9.

Referring to FIG. 9, in the pixel array 1100″ of the image sensor of the embodiment, one of a plurality of first to fourth unit pixels U₁, U₂, U₃, and U₄ may include autofocus pixels AF configured to perform an autofocus function instead of color separation. Referring to FIG. 10, among lens array regions 140a″ corresponding to a unit pattern 1100a″ shown in FIG. 9, a lens array region 140d provided in the autofocus pixels AF may include nanostructures NP configured to collect incident light in a unit pixel in which the autofocus pixels AF are provided, and the other regions may include nanostructures NP configured to perform color separation.

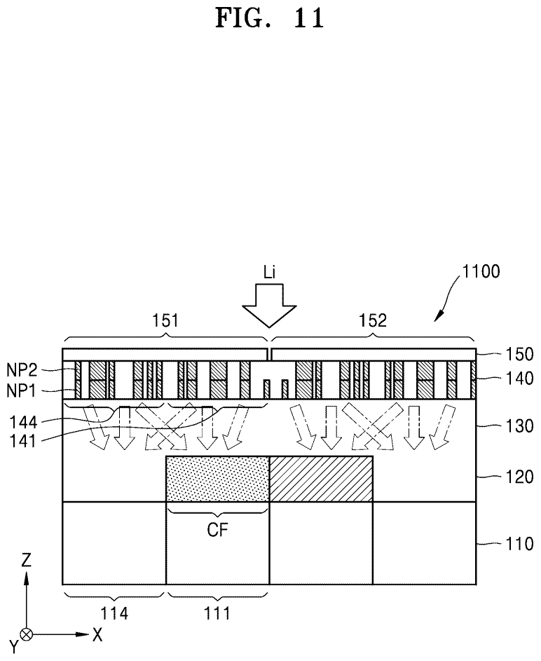

FIG. 11 is a schematic perspective view illustrating some components of the pixel array 1100 of the image sensor 1000 shown in FIG. 2, according to an embodiment. FIG. 11 will now be described with reference to FIGS. 2 and 3, focusing on the difference from FIGS. 2 and 3.

Referring to FIG. 11, the color separation lens array 140 may include a plurality of nanostructures (e.g., first nanostructures NP1 and second nanostructures NP2) having a multilayer structure. A plurality of first nanostructures NP1 may be provided on the spacer layer 130, and a plurality of second nanostructures NP2 may be provided on the first nanostructures NP1. The arrangement of the first nanostructures NP1 and the arrangement of the second nanostructures NP2 may be identical to each other. Alternatively, the arrangement of the first nanostructures NP1 and the arrangement of the second nanostructures NP2 may be different from each other.

In addition, although FIGS. 2 and 3 illustrates that the color filters CF are respectively provided on the first to fourth photodetection cells 111, 112, 113, and 114, FIG. 11 illustrates that color filters CF are provided on only some of the first to fourth photodetection cells 111, 112, 113, and 114. For example, color filters CF may be provided on the first photodetection cell 111 and the second photodetection cell 112 configured to detect light of the same wavelength. Because the color filters CF are provided only on the first photodetection cell 111 and the second photodetection cell 112 configured to detect a phase difference signal among the first to fourth photodetection cells 111, 112, 113, and 114, contrast for phase difference signal detection may be guaranteed.

In the image sensors of the embodiments described above, a pixel color combination and an arrangement of nanostructures may be varied in each of the unit pixels of the pixel array to detect phase difference for performing autofocusing on all colors of light and maintain demosaic-free characteristics.

The image sensors may be incorporated into various high-performance optical or electronic apparatuses. Examples of the electronic apparatuses may include, but are not limited to, smartphones, cellular phones, mobile phones, personal digital assistants (PDAs), laptops, PCs, portable devices, household appliances, security cameras, medical cameras, automotive systems, Internet of things (IoT) devices, augmented reality (AR) devices, virtual reality (VR) devices, other extended reality (XR) devices that enhance user experiences, and other mobile or non-mobile computing devices.

The electronic apparatuses may include, in addition to the image sensor 1000, a processor such as an application processor (AP) to control the image sensor 1000. The processor may operate an operating system or applications to control various hardware or software components and perform data processing and computations. The processor may also include a graphics processing unit (GPU) and/or an image signal processor. When the processor includes an image signal processor, images (or videos) captured by the image sensor 1000 may be stored or output using the processor.

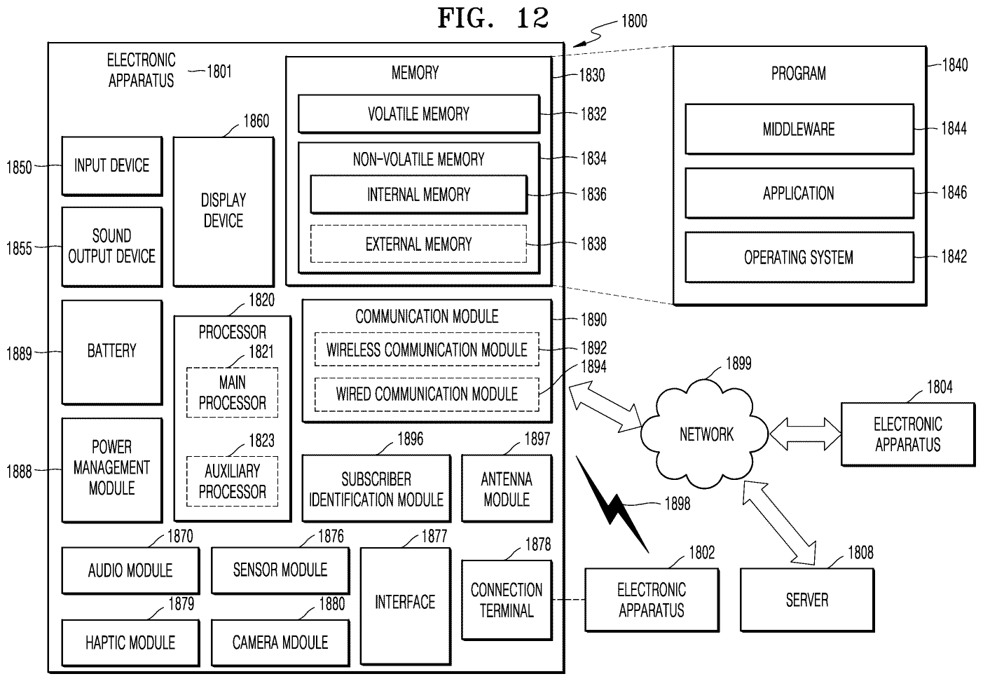

FIG. 12 is a block diagram schematically illustrating an electronic apparatus 1801 including an image sensor according to an embodiment.

Referring to FIG. 12, in a network environment 1800, the electronic apparatus 1801 may communicate with another electronic apparatus 1802 through a first network 1898 (e.g., a near-field wireless communication network or the like) or may communicate with another electronic apparatus 1804 and/or a server 1808 through a second network 1899 (e.g., a far-field wireless communication network or the like). The electronic apparatus 1801 may communicate with the electronic apparatus 1804 through the server 1808. The electronic apparatus 1801 may include a processor 1820, a memory 1830, an input device 1850, a sound output device 1855, a display device 1860, an audio module 1870, a sensor module 1876, an interface 1877, a haptic module 1879, a camera module 1880, a power management module 1888, a battery 1889, a communication module 1890, a subscriber identification module 1896, and/or an antenna module 1897. Some (e.g., the display device 1860 or the like) of the components may be omitted from the electronic apparatus 1801, and/or other components may be added to the electronic apparatus 1801. Some of the components may be implemented in one integrated circuit. For example, the sensor module 1876 (e.g., a fingerprint sensor, an iris sensor, an illuminance sensor, or the like) may be embedded in the display device 1860 (e.g., a display or the like).

The processor 1820 may execute software (e.g., a program 1840 or the like) to control one or more other components (e.g., hardware or software components or the like) of the electronic apparatus 1801 connected to the processor 1820, and may perform a variety of data processing or operations. As a portion of the data processing or operations, the processor 1820 may load instructions and/or data received from other components (e.g., the sensor module 1876, the communication module 1890, or the like) into a volatile memory 1832, process the instructions and/or data stored in the volatile memory 1832, and store result data in a non-volatile memory 1834. The processor 1820 may include a main processor 1821 (e.g., a central processing unit, an AP, or the like) and an auxiliary processor 1823 (e.g., a GPU, an image signal processor, a sensor hub processor, a communication processor, or the like), which is operated independently or together with the main processor 1821. The auxiliary processor 1823 may consume less power than the main processor 1821 and may perform specialized functions.

The auxiliary processor 1823 may control functions and/or states related to some (e.g., the display device 1860, the sensor module 1876, the communication module 1890, or the like) of the components of the electronic apparatus 1801 on behalf of the main processor 1821 while the main processor 1821 is in an inactive (e.g., sleep) state or together with the main processor 1821 while the main processor 1821 is in an active (e.g., application execution) state. The auxiliary processor 1823 (e.g., an image signal processor, a communication processor, or the like) may be implemented as a portion of other functionally relevant components (e.g., the camera module 1880, the communication module 1890, or the like).

The memory 1830 may store a variety of data required by the components (e.g., the processor 1820, the sensor module 1876, or the like) of the electronic apparatus 1801. The data may include, for example, software (e.g., the program 1840 or the like), and input data and/or output data for commands related thereto. The memory 1830 may include the volatile memory 1832 and/or the non-volatile memory 1834.

The program 1840 may be stored as software in the memory 1830, and may include an operating system 1842, middleware 1844, and/or an application 1846.

The input device 1850 may receive commands and/or data to be used for the components (e.g., the processor 1820 or the like) of the electronic apparatus 1801 from the outside (e.g., a user or the like) of the electronic apparatus 1801. The input device 1850 may include a microphone, a mouse, a keyboard, and/or a digital pen (e.g., a stylus pen or the like).

The sound output device 1855 may output an audio signal to the outside of the electronic apparatus 1801. The sound output device 1855 may include a speaker and/or a receiver. The speaker may be used for general purposes such as multimedia playback or record playback, and the receiver may be used to receive incoming calls. The receiver may be provided as a portion of the speaker or may be implemented as a separate device.

The display device 1860 may visually provide information to the outside of the electronic apparatus 1801. The display device 1860 may include a device, such as a display, a hologram device, or a projector, and a control circuit for controlling the device. The display device 1860 may include touch circuitry set to sense a touch, and/or sensor circuitry (e.g., a pressure sensor or the like) configured to measure the intensity of force generated by the touch.

The audio module 1870 may convert sound into an electrical signal, and vice versa. The audio module 1870 may obtain sound through the input device 1850, or may output sound through the sound output device 1855 and/or speakers and/or headphones of another electronic apparatus (e.g., the electronic apparatus 1802 or the like) directly or wirelessly connected to the electronic apparatus 1801.

The sensor module 1876 may detect an operating state (e.g., power, temperature, or the like) of the electronic apparatus 1801 or an external environmental state (e.g., user state or the like), and may generate an electrical signal and/or a data value corresponding to the detected state. The sensor module 1876 may include a gesture sensor, a gyro sensor, a barometric sensor, a magnetic sensor, an acceleration sensor, a grip sensor, a proximity sensor, a color sensor, an infrared (IR) sensor, a biological sensor, a temperature sensor, a humidity sensor, and/or an illuminance sensor.

The interface 1877 may support one or more designated protocols, which may be used to directly or wirelessly connect the electronic apparatus 1801 with other electronic apparatuses (e.g., the electronic apparatus 1802 or the like). The interface 1877 may include a high definition multimedia interface (HDMI), a universal serial bus (USB) interface, a secure digital (SD) card interface, and/or an audio interface.

A connection terminal 1878 may include a connector through which the electronic apparatus 1801 may be physically connected to other electronic apparatuses (e.g., the electronic apparatus 1802 or the like). The connection terminal 1878 may include an HDMI connector, a USB connector, an SD card connector, and/or an audio connector (e.g., a headphone connector or the like).

The haptic module 1879 may convert an electrical signal into a mechanical stimulus (e.g., vibration, movement, or the like) or an electrical stimulus that a user may perceive through tactile sensation or kinesthesia. The haptic module 1879 may include a motor, a piezoelectric element, and/or an electric stimulation device.

The camera module 1880 may capture a still image and a moving image. The camera module 1880 may include a lens assembly having one or more lenses, the image sensor 1000 shown in FIG. 1, an image signal processor, and/or a flash. The lens assembly included in the camera module 1880 may collect light coming from an object to be imaged.

The power management module 1888 may manage power supplied to the electronic apparatus 1801. The power management module 1888 may be implemented as a portion of a power management integrated circuit (PMIC).

The battery 1889 may supply power to components of the electronic apparatus 1801. The battery 1889 may include a non-rechargeable primary battery, a rechargeable secondary battery, and/or a fuel cell.

The communication module 1890 may support establishment of a direct (e.g., wired) communication channel and/or a wireless communication channel between the electronic apparatus 1801 and other electronic apparatuses (e.g., the electronic apparatus 1802, the electronic apparatus 1804, the server 1808, or the like), and communication through the established communication channel. The communication module 1890 operates independently of the processor 1820 (e.g., an AP or the like) and may include one or more communication processors supporting direct communication and/or wireless communication. The communication module 1890 may include a wireless communication module 1892 (e.g., a cellular communication module, a short-range wireless communication module, a global navigation satellite system (GNSS), or the like) and/or a wired communication module 1894 (e.g., a local area network (LAN) communication module, a power line communication module, or the like). A corresponding communication module from among these communication modules may communicate with other electronic apparatuses through the first network 1898 (e.g., a local area network such as Bluetooth, Wi-Fi Direct, or IR data association (IrDA)) or the second network 1899 (e.g., a telecommunication network such as a cellular network, the Internet, or computer networks (e.g., LAN, WAN, or the like)). These various types of communication modules may be integrated into a single component (e.g., a single chip or the like) or may be implemented as a plurality of separate components (e.g., a plurality of chips). The wireless communication module 1892 may identify and authenticate the electronic apparatus 1801 within a communication network such as the first network 1898 and/or the second network 1899 using subscriber information (e.g., an international mobile subscriber identifier (IMSI) or the like) stored in the subscriber identification module 1896.

The antenna module 1897 may transmit and/or receive signals and/or power to and/or from the outside (e.g., other electronic apparatuses or the like). An antenna may include a radiator made of a conductive pattern formed on a substrate (e.g., a printed circuit board (PCB) or the like). The antenna module 1897 may include one or more such antennas. When a plurality of antennas are included in the antenna module 1897, the communication module 1890 may select an antenna suitable for a communication method used in a communication network, such as the first network 1898 and/or the second network 1899, among the plurality of antennas. Signals and/or power may be transmitted or received between the communication module 1890 and other electronic apparatuses through the selected antenna. Other components (e.g., a radio frequency integrated circuit (RFIC) or the like) besides the antenna may be included as part of the antenna module 1897.

Some of the components may be connected to each other and exchange signals (e.g., commands, data, or the like) through a communication method between peripheral devices (e.g., a bus, general purpose input and output (GPIO), a serial peripheral interface (SPI), a mobile industry processor interface (MIPI), or the like).

Commands or data may be transmitted or received between the electronic apparatus 1801 and an external apparatus such as the electronic apparatus 1804 through the server 1808 connected to the second network 1899. The other electronic apparatuses 1802 and 1804 may be the same as or different from the electronic apparatus 1801. All or some of the operations of the electronic apparatus 1801 may be executed by one or more of the other electronic apparatuses (e.g., the electronic apparatus 1802, the electronic apparatus 1804, and the server 1808). For example, when the electronic apparatus 1801 needs to perform certain functions or services, the electronic apparatus 1801 may request one or more other electronic apparatuses to perform some or all of the functions or services instead of directly executing the functions or services. One or more other electronic apparatuses that have received the request may execute an additional function or service related to the request, and may transfer results of the execution to the electronic apparatus 1801. To this end, cloud computing, distributed computing, and/or client-server computing techniques may be used.

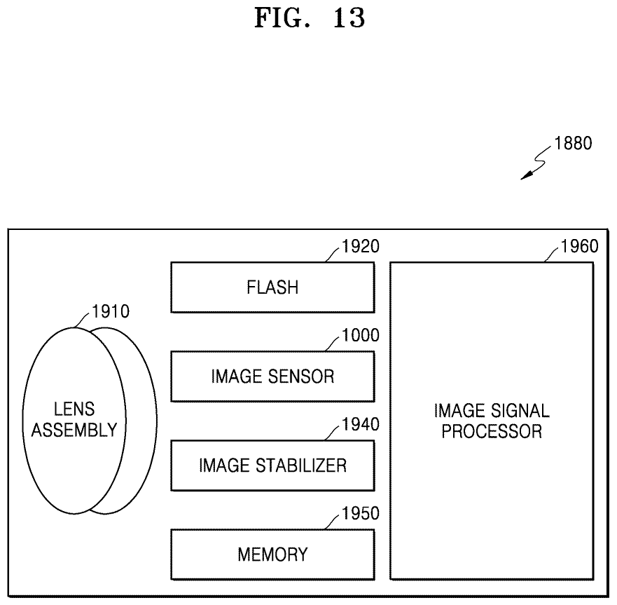

FIG. 13 is a block diagram illustrating the camera module 1880 shown in FIG. 12.

Referring to FIG. 13, the camera module 1880 may include a lens assembly 1910, a flash 1920, the image sensor 1000 (refer to FIG. 1), an image stabilizer 1940, a memory 1950 (e.g., a buffer memory, or the like), and/or an image signal processor 1960. The lens assembly 1910 may collect light emitted from an object to be photographed. The camera module 1880 may include a plurality of lens assemblies 1910, and in this case, the camera module 1880 may include a dual camera, a 360-degree camera, or a spherical camera. Some of the lens assemblies 1910 may have the same lens attributes (e.g., a viewing angle, a focal length, auto focus, F Number, optical zoom, and the like) as each other, or different lens attributes from each other. The lens assembly 1910 may include a wide angle lens or a telescopic lens.

The flash 1920 may emit light to reinforce light emitted or reflected from an object. The flash 1920 may include one or a plurality of light-emitting diodes (e.g., a red-green-blue (RGB) light-emitting diode (LED), a white LED, an infrared (IR) LED, an ultraviolet (UV) LED, or the like), and/or a xenon lamp. The image sensor 1000 may be the image sensor 1000 described with reference to FIG. 1. The image sensor 1000 may convert light, which is emitted or reflected from an object and transmitted through the lens assembly 1910, into an electrical signal, thereby obtaining an image corresponding to the object. The image sensor 1000 may include one or more image sensors selected from image sensors with different characteristics, such as RGB sensors, black and white (BW) sensors, IR sensors, and UV sensors. Each sensor included in the image sensor 1000 may be implemented as a CCD sensor and/or a CMOS sensor.

The image stabilizer 1940 may move, in response to a movement of the camera module 1880 or the electronic apparatus 1801 including the camera module 1880, one or a plurality of lenses included in the lens assembly 1910 or the image sensor 1000 in a particular direction, or may control the movement characteristics (read-out timing or the like) of the image sensor 1000, thereby compensating for a negative affect caused by the movement of the camera module 1880. The image stabilizer 1940 may detect a movement of the camera module 1880 or the electronic apparatus 1801 by using a gyro sensor or an acceleration sensor arranged inside or outside the camera module 1880. The image stabilizer 1940 may be implemented in an optical form.

The memory 1950 may store a part or entire data of an image obtained through the image sensor 1000 for a subsequent image processing operation. For example, when a plurality of images are obtained at high speed, only low resolution images may be displayed while the obtained original data (e.g., Bayer-patterned data, high resolution data, and the like) is stored in the memory 1950. Then, the memory 1950 may be used to transmit the original data of a selected (e.g., user selection or the like) image to the image signal processor 1960. The memory 1950 may be incorporated into the memory 1830 of the electronic apparatus 1801, or configured to be an independently operated separate memory.

The image signal processor 1960 may perform image processing on an image obtained through the image sensor 1000 or the image data stored in the memory 1950. The image processing may include depth map generation, 3D modeling, panorama generation, feature point extraction, image synthesis, and/or image compensation (e.g., noise reduction, resolution adjustment, brightness adjustment, blurring, sharpening, softening, and the like). The image signal processor 1960 may perform control (e.g., exposure time control, read-out timing control, or the like) on constituent elements (e.g., the image sensor 1000 or the like) included in the camera module 1880. The image processed by the image signal processor 1960 may be stored again in the memory 1950 for additional processing or provided to external devices (e.g., the memory 1830, the display device 1860, the electronic apparatus 1802, the electronic apparatus 1804, the server 1808, and the like) provided outside the camera module 1880. The image signal processor 1960 may be incorporated into the processor 1820, or configured to be a separate processor operated independently of the processor 1820. When the image signal processor 1960 is implemented as a processor separate from the processor 1820, the image processed by the image signal processor 1960 may undergo additional image processing by the processor 1820 and then displayed through the display device 1860.

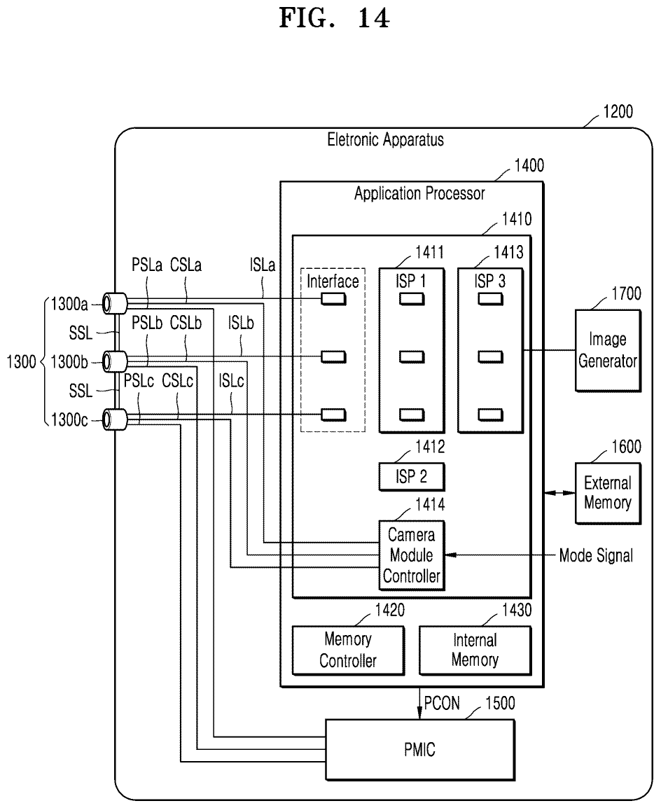

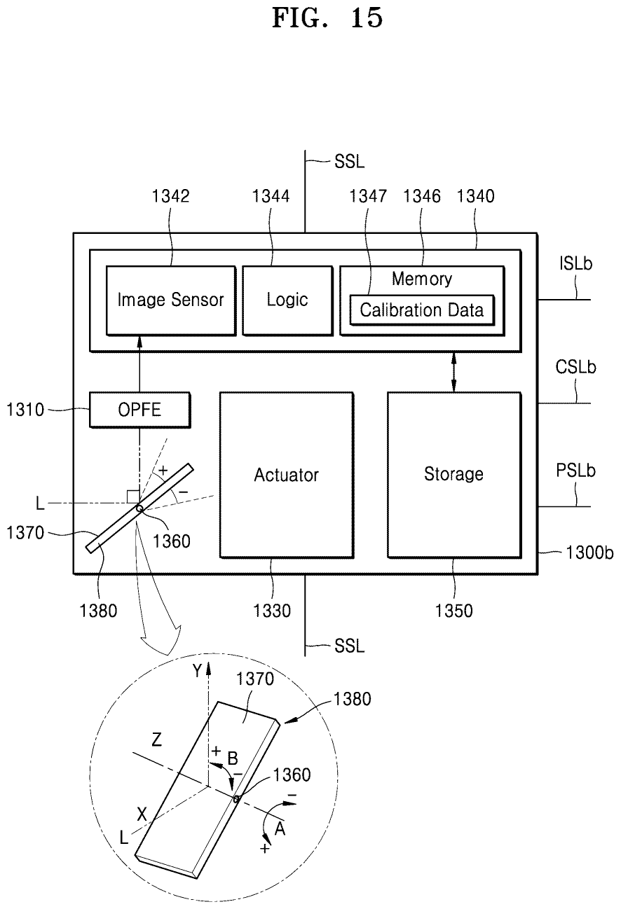

FIG. 14 is a block diagram illustrating an electronic apparatus 1200 including a plurality of camera modules, and FIG. 15 is a block diagram illustrating a camera module 1300b of the electronic apparatus 1200 shown in FIG. 14.

Referring to FIG. 14, the electronic apparatus 1200 may include a camera module group 1300, an application processor 1400, a PMIC 1500, an external memory 1600, and an image generator 1700.

The camera module group 1300 may include a plurality of camera modules 1300a, 1300b, and 1300c. Although three camera modules 1300a, 1300b, and 1300c are illustrated in FIG. 14, embodiments are not limited thereto. In some embodiments, the camera module group 1300 may be modified to include only two camera modules. In some embodiments, the camera module group 1300 may be modified to include n camera modules (n refers to a natural number greater than or equal to 4).

The configuration of the camera module 1300b will be described below with reference to FIG. 15. The following description of the camera module 1300b may also be applied to the other camera modules 1300a and 1300c.

Referring to FIG. 15, the camera module 1300b may include a prism 1380, an optical path folding element (OPFE) 1310, an actuator 1330, an image sensing device 1340, and a storage 1350.

The prism 1380 may include a reflective surface 1370 of a light reflecting material and may change the path of light L incident from the outside.

In some embodiments, the prism 1380 may change the path of light L incident in a first direction (X direction) to a second direction (Y direction) perpendicular to the first direction (X direction). The prism 1380 may rotate the reflective surface 1370 of the light reflecting material in a direction A around a center shaft 1360 or rotate the center shaft 1360 in a direction B to change the path of light L incident in the first direction (X direction) to the second direction (Y direction) perpendicular to the first direction (X direction). In this case, the OPFE 1310 may move in a third direction (Z direction) that is perpendicular to both of the first direction (X direction) and the second direction (Y direction).

In some embodiments, as illustrated in FIG. 15, an A-direction maximum rotation angle of the prism 1380 may be less than or equal to 15 degrees in a positive (+) direction A and greater than 15 degrees in a negative (−) direction A. However, embodiments are not limited thereto.

In some embodiments, the prism 1380 may move by an angle of about 20 degrees or in a range from about 10 degrees to about 20 degrees or from about 15 degrees to about 20 degrees in a positive (+) or negative (−) direction B. In this case, an angle by which the prism 1380 moves in the positive (+) direction B may be the same as or similar, within a difference of about 1 degree, to an angle by which the prism 1380 moves in the negative (−) direction B.

In some embodiments, the prism 1380 may move the reflective surface 1370 of the light reflecting material in the third direction (Z direction) that is parallel with an extension direction of the center shaft 1360.

The OPFE 1310 may include, for example, m optical lenses where m refers to a natural number. The m optical lenses may move in the second direction (Y direction) and change an optical zoom ratio of the camera module 1300b. For example, when the default optical zoom ratio of the camera module 1300b is Z, the optical zoom ratio of the camera module 1300b may be changed to 3Z, 5Z, 10Z, or greater by moving the m optical lenses included in the OPFE 1310.

The actuator 1330 may move the OPFE 1310 or the m optical lenses (hereinafter referred to as the optical lens) to a certain position. For example, the actuator 1330 may adjust the position of the optical lens such that an image sensor 1342 may be positioned at a focal length of the optical lens for accurate sensing.

The image sensing device 1340 may include the image sensor 1342, control logic 1344, and memory 1346. The image sensor 1342 may sense an image of a target by using light L provided through the optical lens. The control logic 1344 may control the overall operation of the camera module 1300b. For example, the control logic 1344 may control the operation of the camera module 1300b according to control signals provided through a control signal line CSLb.

The memory 1346 may store information, such as calibration data 1347, for operations of the camera module 1300b. The calibration data 1347 may include information for the camera module 1300b to generate image data using light L incident from the outside. For example, the calibration data 1347 may include information about the degree of rotation, information about a focal length, information about an optical axis, or the like. When the camera module 1300b is implemented as a multi-state camera that has a focal length varying with the position of the optical lens, the calibration data 1347 may include a focal length value for each position (or state) of the optical lens and information about auto focusing.

The storage 1350 may store image data sensed by the image sensor 1342. The storage 1350 may be provided outside the image sensing device 1340 and may form a stack with a sensor chip of the image sensing device 1340. In some embodiments, the storage 1350 may include electrically erasable programmable read-only memory (EEPROM). However, embodiments are not limited thereto.

Referring to FIGS. 14 and 15, in some embodiments, the camera modules 1300a, 1300b, and 1300c may respectively include actuators 1330. In this case, the camera modules 1300a, 1300b, and 1300c may include the same or different pieces of calibration data 1347 according to operations of the actuators 1330 of the camera modules 1300a, 1300b, and 1300c.

In some embodiments, one (e.g., the camera module 1300b) of the camera modules 1300a, 1300b, and 1300c may be of a folded-lens type including the prism 1380 and the OPFE 1310 while the other camera modules (e.g., the camera modules 1300a and 1300b) may be of a vertical type that does not include the prism 1380 and the OPFE 1310. However, embodiments are not limited thereto.

In some embodiments, one (e.g., the camera module 1300c) of the camera modules 1300a, 1300b, and 1300c may include a depth camera of a vertical type that is capable of extracting depth information using IR rays.

In some embodiments, at least two camera modules (e.g., the camera modules 1300a and 1300b) among the camera modules 1300a, 1300b, and 1300c may have different fields of view. In this case, for example, the at least two camera modules (e.g., the camera modules 1300a and 1300b) among the camera modules 1300a, 1300b, and 1300c may respectively have different optical lenses. However, embodiments are not limited thereto.

In some embodiments, the camera modules 1300a, 1300b, and 1300c may have fields of view that are different from each other. In this case, the camera modules 1300a, 1300b, and 1300c may have different optical lenses. However, embodiments are not limited thereto.

In some embodiments, the camera modules 1300a, 1300b, and 1300c may be physically separated from each other. That is, instead of dividing the sensing area of one image sensor 1342 for the camera modules 1300a, 1300b, and 1300c, the camera modules 1300a, 1300b, and 1300c may respectively include independent image sensors 1342.

Referring back to FIG. 14, the application processor 1400 may include an image processing unit 1410, a memory controller 1420, and an internal memory 1430. The application processor 1400 may be implemented separately from the camera modules 1300a, 1300b, and 1300c. For example, the application processor 1400 and the camera modules 1300a, 1300b, and 1300c may be implemented in different semiconductor chips separate from each other.

The image processing unit 1410 may include a plurality of image processors 1411, 1412, and 1413, and a camera module controller 1414.

Pieces of image data respectively generated by the camera modules 1300a, 1300b, and 1300c may be provided to the image processing unit 1410 respectively through image signal lines ISLa, ISLb, and ISLc separated from each other. Such image data transmission may be performed using, for example, camera serial interface (CSI) that is based on MIPI. However, embodiments are not limited thereto.

The image data transmitted to the image processing unit 1410 may be stored in the external memory 1600 before being transferred to the image processors 1411 and 1412. The image data stored in the external memory 1600 may be provided to the image processor 1411 and/or the image processor 1412. The image processor 1411 may correct the received image data to generate a moving image. The image processor 1412 may correct the received image data to generate a still image. For example, the image processors 1411 and 1412 may perform preprocessing operations such as color correction and gamma correction on the image data.

The image processor 1411 may include sub-processors. When the number of sub-processors is equal to the number of camera modules 1300a, 1300b, and 1300c, each of the sub-processors may process image data provided by one camera module. When the number of sub-processors is less than the number of camera modules 1300a, 1300b, 1300c, at least one of the sub-processors may process image data provided by a plurality of camera modules through a time-sharing process. The image data processed by the image processor 1411 and/or the image processor 1412 may be stored in the external memory 1600 before being transferred to the image processor 1413. The image data stored in the external memory 1600 may be transferred to the image processor 1413. The image processor 1413 may perform post-processing operations such as noise correction and sharpening correction on the image data.

The image data processed by the image processor 1413 may be provided to the image generator 1700. The image generator 1700 may generate a final image according to image generation information or a mode signal by using the image data received from the image processor 1413.

For example, according to the image generation information or the mode signal, the image generator 1700 may generate an output image by merging at least portions of pieces of image data that are respectively generated by the camera modules 1300a, 1300b, and 1300c having different fields of view. In addition, according to the image generation information or the mode signal, the image generator 1700 may generate an output image by selecting one of pieces of image data that are respectively generated by the camera modules 1300a, 1300b, and 1300c having different fields of view.

In some embodiments, the image generation information may include a zoom signal or a zoom factor. In some embodiments, the mode signal may be based on a mode selected by a user.

When the image generation information includes a zoom signal (e.g., zoom factor) and the camera modules 1300a, 1300b, and 1300c have different fields of view, the image generator 1700 may perform different operations according to the type of the zoom signal. For example, when the zoom signal is a first signal, the image generator 1700 may merge image data output from the camera module 1300a with image data output from the camera module 1300c, and may then generate an output image by using the merged image data (e.g., merged image signal) and image data that is output from the camera module 1300b and not merged with other image data. When the zoom signal is a second signal different from the first signal, the image generator 1700 may generate an output image by selecting one of the pieces of image data respectively output from the camera modules 1300a, 1300b, and 1300c, instead of merging the pieces of image data with each other. However, embodiments are not limited thereto, and a method of processing image data may be changed.

The camera module controller 1414 may provide a control signal to each of the camera modules 1300a, 1300b, and 1300c. Control signals generated by the camera module controller 1414 may be provided to the camera modules 1300a, 1300b, and 1300c through separate control signal lines CSLa, CSLb, and CSLc.

In some embodiments, a control signal provided from the camera module controller 1414 to each of the camera modules 1300a, 1300b, and 1300c may include mode information relating to a mode signal. The camera modules 1300a, 1300b, and 1300c may operate in a first operation mode or a second operation mode in relation with a sensing speed based on the mode information.

In the first operation mode, the camera modules 1300a, 1300b, and 1300c may generate an image signal at a first speed (e.g., at a first frame rate), encode the image signal at a second speed greater than the first speed (e.g., at a second frame rate greater than the first frame rate), and transmit the encoded image signal to the application processor 1400. In this case, the second speed may be less than or equal to 30 times the first speed.

The application processor 1400 may store the received image signal, that is, the encoded image signal, in the internal memory 1430 or the external memory 1600 provided outside the application processor 1400. Thereafter, the application processor 1400 may read the encoded image signal from the internal memory 1430 or the external memory 1600, decode the encoded image signal, and display image data generated based on the decoded image signal. For example, the image processors 1411 and 1412 of the image processing unit 1410 may decode the encoded image signal and may also perform image processing on the decoded image signal.

In the second operation mode, the camera modules 1300a, 1300b, and 1300c may generate an image signal at a third speed less than the first speed (e.g., at a third frame rate less than the first frame rate) and may transmit the image signal to the application processor 1400. The image signal provided to the application processor 1400 may be a non-encoded image signal. The application processor 1400 may perform image processing on the image signal or store the image signal in the internal memory 1430 or the external memory 1600.

The PMIC 1500 may provide power, for example, power supply voltage, to each of the camera modules 1300a, 1300b, and 1300c. For example, under control by the application processor 1400, the PMIC 1500 may provide a first piece of power to the camera module 1300a through a power signal line PSLa, a second piece of power to the camera module 1300b through a power signal line PSLb, and a third piece of power to the camera module 1300c through a power signal line PSLc.

The PMIC 1500 may generate power corresponding to each of the camera modules 1300a, 1300b, and 1300c and may adjust the level of power, in response to a power control signal PCON received from the application processor 1400. The power control signal PCON may include a power adjustment signal for each operation mode of the camera modules 1300a, 1300b, and 1300c. For example, the operation mode may include a low-power mode. In this case, the power control signal PCON may include information about a camera module to be operated in the low-power mode and information on a set power level. The same level or different levels of power may be provided to the camera modules 1300a, 1300b, and 1300c. In addition, the level of power may be dynamically varied.

According to one or more of the embodiments described above, in the image sensors and the electronic apparatuses including the image sensors, a pixel color combination and an arrangement of nanostructures may be varied in the unit pixels of the pixel array to detect phase difference signals for performing autofocusing on all colors of light and maintain demosaic-free characteristics.

It should be understood that the example embodiments described herein should be considered in a descriptive sense only and not for purposes of limitation. Descriptions of features or aspects within each example embodiment of the present disclosure should typically be considered as available for other similar features or aspects in other embodiments of the present disclosure. While one or more non-limiting example embodiments have been described with reference to the figures, it will be understood by those of ordinary skill in the art that various changes in form and details may be made therein without departing from the spirit and scope of the present disclosure.

What is claimed is:

1. An image sensor comprising:
a sensor substrate comprising a plurality of photodetection cells;
a spacer layer on the sensor substrate; and
a color separation lens array on the spacer layer and comprising a plurality of nanostructures,
wherein the image sensor further comprises a plurality of unit pixels, each of the plurality of unit pixels comprising a plurality of pixels,
wherein the plurality of pixels are defined by respective ones of the plurality of photodetection cells, and by the plurality of nanostructures,
wherein the plurality of nanostructures are configured to split incident light according to wavelengths of the incident light within each of the plurality of unit pixels and collect the incident light, that is split, in corresponding ones of the plurality of pixels,
wherein at least two pixels, from among the plurality of pixels, of each of the plurality of unit pixels are configured to detect light of an identical wavelength, and
wherein a wavelength of light detected by the at least two pixels of one of the plurality of unit pixels is different from a wavelength of light detected by the at least two pixels of another one of the plurality of unit pixels.

2. The image sensor of claim 1, wherein the plurality of unit pixels comprise a first unit pixel and a second unit pixel, and the plurality of pixels of each of the first unit pixel and the second unit pixel comprises a first pixel, a second pixel, and a third pixel,
wherein the first pixel and the second pixel of the first unit pixel are configured to detect light of a first wavelength, the third pixel of the first unit pixel is configured to detect light of a wavelength different from the first wavelength, the first pixel and the second pixel of the second unit pixel are configured to detect light of a second wavelength, the third pixel of the second unit pixel is configured to detect light of a wavelength different from the second wavelength, and the second wavelength is different from the first wavelength.

3. The image sensor of claim 1, wherein the plurality of unit pixels comprise a first unit pixel, a second unit pixel, and a third unit pixel, and the plurality of pixels of each of the first unit pixel, the second unit pixel, and the third unit pixel comprises a first pixel, a second pixel, and a third pixel,
wherein the first pixel and the second pixel of the first unit pixel are configured to detect light of a first wavelength, the third pixel of the first unit pixel is configured to detect light of a wavelength different from the first wavelength, the first pixel and the second pixel of the second unit pixel are configured to detect light of a second wavelength, the third pixel of the second unit pixel is configured to detect light of a wavelength different from the second wavelength, the first pixel and the second pixel of the third unit pixel are configured to detect light of a third wavelength, the third pixel of the third unit pixel is configured to detect light of a wavelength different from the third wavelength, and the first wavelength, the second wavelength, and the third wavelength are different from each other.

4. The image sensor of claim 1, wherein the plurality of unit pixels define a plurality of unit patterns,
wherein each of the plurality of unit patterns comprises, from among the plurality of unit pixels, a first unit pixel, a second unit pixel, a third unit pixel, and a fourth unit pixel that are arranged in a 2×2 array,
wherein each of the first unit pixel, the second unit pixel, the third unit pixel, and the fourth unit pixel comprises, from among the plurality of pixels, a first pixel, a second pixel, a third pixel, and a fourth pixel arranged in a 2×2 array,
wherein the first pixel and the second pixel of the first unit pixel are configured to detect light of a first wavelength, the third pixel of the first unit pixel is configured to detect light of a second wavelength, and the fourth pixel of the first unit pixel is configured to detect light of a third wavelength,
wherein the first pixel and the second pixel of the second unit pixel are configured to detect the light of the second wavelength, the third pixel of the second unit pixel is configured to detect the light of the third wavelength, and the fourth pixel of the second unit pixel is configured to detect the light of the first wavelength,
wherein the first pixel and the second pixel of the third unit pixel are configured to detect the light of the third wavelength, the third pixel of the third unit pixel is configured to detect the light of the first wavelength, and the fourth pixel of the third unit pixel is configured to detect the light of the second wavelength, and
wherein the first pixel and the second pixel of the fourth unit pixel are configured to detect the light of the first wavelength, the third pixel of the fourth unit pixel is configured to detect the light of the second wavelength, the fourth pixel of the fourth unit pixel is configured to detect the light of the third wavelength, and the first wavelength, the second wavelength, and the third wavelength are different from each other.

5. The image sensor of claim 1, wherein a number of the plurality of unit pixels that comprise at least two pixels, from among the plurality of pixels, that are configured detect light of a first wavelength is equal to k,
wherein a number of the plurality of unit pixels that comprise at least two pixels, from among the plurality of pixels, that are configured detect light of a second wavelength is equal to l,
wherein a number of the plurality of unit pixels that comprise at least two pixels, from among the plurality of pixels, that are configured detect light of a third wavelength among the plurality of unit pixels is equal to m, and
wherein at least two from k, l, and m are different from each other.

6. The image sensor of claim 1, wherein the plurality of nanostructures are symmetrical with respect a diagonal direction within each of the plurality of unit pixels.

7. The image sensor of claim 2, wherein the first pixel and the second pixel of each of the plurality of unit pixels are arranged with respect to each other in a first diagonal direction, and the plurality of nanostructures defining each of the plurality of unit pixels are symmetrical with respect to a second diagonal direction different from the first diagonal direction.

8. The image sensor of claim 7, wherein the image sensor comprises a first corresponding region that is defined by the first pixel, and a second corresponding region that is defined by the second pixel, and
wherein an arrangement of the plurality of nanostructures in the first corresponding region is a rotation of an arrangement of the plurality of nanostructures in the second corresponding region.

9. The image sensor of claim 1, wherein the at least two pixels of each of the plurality of unit pixels, which are configured to detect the light of the identical wavelength, are further configured to perform an autofocus function.

10. The image sensor of claim 1, further comprising a plurality of optical diffusers on the color separation lens array and respectively corresponding to the plurality of unit pixels.

11. The image sensor of claim 1, further comprising a color filter layer between the sensor substrate and the spacer layer, the color filter layer comprising a plurality of color filters,
wherein each of the plurality of color filters is on the at least two pixels of each of the plurality of unit pixels, which are configured to detect the light of the identical wavelength.

12. An electronic apparatus comprising:
a lens assembly comprising at least one lens and configured to form an optical image of an object;
an image sensor configured to convert the optical image formed by the lens assembly into an electrical signal; and
a processor configured to process a signal generated by the image sensor,
wherein the image sensor comprises:
a sensor substrate comprising a plurality of photodetection cells;
a spacer layer on the sensor substrate; and
a color separation lens array on the spacer layer and comprising a plurality of nanostructures,
wherein the image sensor further comprises a plurality of unit pixels, each of the plurality of unit pixels comprising a plurality of pixels,
wherein the plurality of pixels are defined by respective ones of the plurality of photodetection cells, and by the plurality of nanostructures,
wherein the plurality of nanostructures are configured to split incident light according to wavelengths of the incident light within each of the plurality of unit pixels and collect the incident light, that is split, in corresponding ones of the plurality of pixels,
wherein at least two pixels, from among the plurality of pixels, of each of the plurality of unit pixels are configured to detect light of an identical wavelength, and
wherein a wavelength of light detected by the at least two pixels of one of the plurality of unit pixels is different from a wavelength of light detected by the at least two pixels of an identical wavelength of another one of the plurality of unit pixels.

13. The electronic apparatus of claim 12, wherein the plurality of unit pixels comprise a first unit pixel and a second unit pixel, and the plurality of pixels of each of the first unit pixel and the second unit pixel comprises a first pixel, a second pixel, and a third pixel,
wherein the first pixel and the second pixel of the first unit pixel are configured to detect light of a first wavelength, the third pixel of the first unit pixel is configured to detect light of a wavelength different from the first wavelength, the first pixel and the second pixel of the second unit pixel are configured to detect light of a second wavelength, the third pixel of the second unit pixel is configured to detect light of a wavelength different from the second wavelength, and the second wavelength is different from the first wavelength.

14. The electronic apparatus of claim 12, wherein the plurality of unit pixels comprise a first unit pixel, a second unit pixel, and a third unit pixel, and the plurality of pixels of each of the first unit pixel, the second unit pixel, and the third unit pixel comprises a first pixel, a second pixel, and a third pixel,
wherein the first pixel and the second pixel of the first unit pixel are configured to detect light of a first wavelength, the third pixel of the first unit pixel is configured to detect light of a wavelength different from the first wavelength, the first pixel and the second pixel of the second unit pixel are configured to detect light of a second wavelength, the third pixel of the second unit pixel is configured to detect light of a wavelength different from the second wavelength, the first pixel and the second pixel of the third unit pixel are configured to detect light of a third wavelength, the third pixel of the third unit pixel is configured to detect light of a wavelength different from the third wavelength, and the first wavelength, the second wavelength, and the third wavelength are different from each other.

15. The electronic apparatus of claim 12, wherein the plurality of unit pixels define a plurality of unit patterns,
wherein each of the plurality of unit patterns comprises, from among the plurality of unit pixels, a first unit pixel, a second unit pixel, a third unit pixel, and a fourth unit pixel that are arranged in a 2×2 array,
wherein each of the first unit pixel, the second unit pixel, the third unit pixel, and the fourth unit pixel comprises, from among the plurality of pixels, a first pixel, a second pixel, a third pixel, and a fourth pixel arranged in a 2×2 array,
wherein the first pixel and the second pixel of the first unit pixel are configured to detect light of a first wavelength, the third pixel of the first unit pixel is configured to detect light of a second wavelength, and the fourth pixel of the first unit pixel is configured to detect light of a third wavelength,
wherein the first pixel and the second pixel of the second unit pixel are configured to detect the light of the second wavelength, the third pixel of the second unit pixel is configured to detect the light of the third wavelength, and the fourth pixel of the second unit pixel is configured to detect the light of the first wavelength,
wherein the first pixel and the second pixel of the third unit pixel are configured to detect the light of the third wavelength, the third pixel of the third unit pixel is configured to detect the light of the first wavelength, and the fourth pixel of the third unit pixel is configured to detect the light of the second wavelength, and
wherein the first pixel and the second pixel of the fourth unit pixel are configured to detect the light of the first wavelength, the third pixel of the fourth unit pixel is configured to detect the light of the second wavelength, the fourth pixel of the fourth unit pixel is configured to detect the light of the third wavelength, and the first wavelength, the second wavelength, and the third wavelength are different from each other.

16. The electronic apparatus of claim 12, wherein a number of the plurality of unit pixels that comprise at least two pixels, from among the plurality of pixels, that are configured detect light of a first wavelength is equal to k,
wherein a number of the plurality of unit pixels that comprise at least two pixels, from among the plurality of pixels, that are configured detect light of a second wavelength is equal to l,
wherein a number of the plurality of unit pixels that comprise at least two pixels, from among the plurality of pixels, that are configured detect light of a third wavelength among the plurality of unit pixels is equal to m, and
wherein at least two from k, l, and m are different from each other.

17. The electronic apparatus of claim 12, wherein the plurality of nanostructures are symmetrical with respect a diagonal direction within each of the plurality of unit pixels.

18. The electronic apparatus of claim 13, wherein the first pixel and the second pixel of each of the plurality of unit pixels are arranged with respect to each other in a first diagonal direction, and the plurality of nanostructures defining each of the plurality of unit pixels are symmetrical with respect to a second diagonal direction different from the first diagonal direction.

19. The electronic apparatus of claim 18, wherein the image sensor comprises a first corresponding region that is defined by the first pixel, and a second corresponding region that is defined by the second pixel, and
wherein an arrangement of the plurality of nanostructures in the first corresponding region is a rotation of an arrangement of the plurality of nanostructures in the second corresponding region.

20. The electronic apparatus of claim 12, further comprising a plurality of optical diffusers on the color separation lens array and respectively corresponding to the plurality of unit pixels.
